(19) United States
(12) Patent Application Publication
(10) Pub. No.: US 2026/0331426 A1
(43) Pub. Date: Oct. 22, 2026

(54) SYSTEMS AND METHODS FOR CONTROLLING MAIN ELECTRODE AND EDGE RING USING NON-SINUSOIDAL PULSES TO ACHIEVE PROCESS RATE UNIFORMITY

(71) Applicant: Lam Research Corporation, Fremont, CA (US)

(72) Inventor: Amit Kumar Singh, Bengaluru, KA (IN)

(21) Appl. No.: 19/486,530

(22) PCT Filed: May 31, 2024
(86) PCT No.: PCT/US2024/031942

§ 371 Date: Nov. 21, 2025

Related U.S. Application Data
(60) Provisional application No. 63/521,322, filed on Jun. 15, 2023.

(51) Int. Cl. H01J 37/32

(52) U.S. Cl. CPC H01J 37/32174; H01J 37/32642; H01J 2237/3323; H01J 2237/3343

(57) ABSTRACT

A system for achieving process rate uniformity is described. The system includes a first power supply, which includes a direct current (DC) power source that generates a DC voltage waveform, a capacitor coupled in parallel to the DC power supply, and a plurality of voltage supplies coupled to the capacitor. The plurality of voltage supplies receive the DC voltage waveform to facilitate generation of a first set of non-sinusoidal radio frequency (RF) pulses, which are supplied to a main electrode of a plasma chamber. The system includes a second power supply that facilitates generation of a second set of non-sinusoidal RF pulses. The second set of non-sinusoidal RF pulses are supplied to an edge electrode of the plasma chamber.

### FIELD

The present embodiments relate to systems and methods for controlling main electrode and edge ring using non-sinusoidal radio frequency (RF) pulses to achieve process rate uniformity.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A plasma tool is used to process a substrate. A radio frequency (RF) generator of the plasma tool is connected to a match network of the plasma tool. The match network is connected to a chuck of a plasma chamber. The match network includes a network of capacitors and inductors. The substrate is placed on top of the chuck in the plasma chamber. One or more gases are supplied to the plasma chamber. Also, an RF signal is generated by the RF generator. The network of capacitors and inductors receives the RF signal and matches impedances between output and input of the match network to output another RF signal, and sends the other RF signal to the plasma chamber for processing the substrate. However, the substrate is not processed in a uniform and efficient way.

### SUMMARY

Embodiments of the disclosure provide systems, apparatus, methods and computer programs for controlling main electrode and edge ring using non-sinusoidal radio frequency (RF) pulses to achieve process rate uniformity. It should be appreciated that the present embodiments can be implemented in numerous ways, e.g., a process, an apparatus, a system, a device, or a method on a computer readable medium. Several embodiments are described below.

In an embodiment, a non-sinusoidal, shaped waveform, sometimes referred to herein as a non-sinusoidal bias (NSB), with fast change in voltage on both rising and falling edges to power our bias electrode is described.

In an embodiment, a main power supply that provides an NSB to a substrate, such as a semiconductor wafer, via a main electrode, coupled with a coordinated tunable edge sheath (TES) power supply that provides an NSB to the edge ring that surrounds the main electrode is described. For example, the main power supply is a circuit housed within a first compartment and the TES power supply is another circuit housed within a separate compartment and there is a control connection between the main and TES power supplies. As another example, an integrated single compartment includes a single integrated circuit having a first portion as the main power supply and a second portion as the TES power supply. Placing both the main and TES power supplies in the same compartment with outputs in close proximity closer to the main electrode and the edge ring reduces parasitic elements as compared to a remote system with a long cable. The remote system may distort non-sinusoidal bias voltage waveforms output from the main and TES power supplies, further downstream.

In one embodiment, independent control of an NSB voltage level for the main power supply and an NSB voltage level for the TES power supply is provided. For example, the main electrode is provided with a main non-sinusoidal voltage waveform and the edge electrode is provided with a TES non-sinusoidal voltage waveform. Voltage of the main non-sinusoidal voltage waveform is controlled to achieve ion flux control at the main electrode and voltage of the TES non-sinusoidal voltage waveform is controlled to achieve ion flux control at the edge ring.

In an embodiment, ion flux compensation for both the main and TES power supplies is provided. For example, there is independent control of ion current compensators' current levels by separate control of slopes of both the main and TES non-sinusoidal voltage waveforms. Moreover, as another example, a phase relationship between the main and TES non-sinusoidal voltage waveforms is controlled to achieve the ion flux compensation.

In one embodiment, co-ordinated multi-level voltage pulsing of voltage levels of the main and TES non-sinusoidal voltage waveforms generated by the main and TES power supplies is provided.

In an embodiment, a coplanar sheath of plasma at the edge ring and the main electrode is generated. The coplanar sheath has a predetermined sheath voltage. The edge ring is consumable. As such, the edge ring wears over time. By controlling the main non-sinusoidal voltage waveform or the TES non-sinusoidal voltage waveform or both to generate the coplanar sheath, independent of a condition of the edge ring, the substrate can be processed in a uniform manner.

In one embodiment, a method for implementing a single control for energy recovery and ion flux compensation is described. Energy stored in the plasma chamber, which is an example of a plasma load, can be recovered and shaped through an active discharge of output. The energy discharge shaping can be carried out through pulse width modulation of a switch. The method provides ion flux compensation, and by controlling the pulse width modulation, different discharge shapes can be achieved. However, the plasma load is an active load, and therefore, the ion flux can generate a voltage ripple when energy is not being discharged. The voltage ripple can be reduced by using high-frequency pulse width modulation.

In an embodiment, the energy recovery and ion flux compensation are controlled separately. For example, an energy recovery circuit is used to achieve the energy recovery and a high voltage (HV) supply is employed to generate a non-sinusoidal waveform to achieve the ion flux compensation.

In an embodiment, a system having two HV direct current (DC) supplies, including a first DC supply and a second DC supply, of a voltage source system are provided. The first and second DC supplies are connected to a ground potential therebetween. The first DC supply is for a charging operation, such as a wafer charging phase, to charge a capacitance of the plasma chamber, whereas the second DC supply is implemented as a controllable DC current source to provide a negative linear charge resulting in a ramp slope, such as a negative slope, at an output of the system. A slope of a non-sinusoidal voltage waveform generated at the output of the system can be controlled by controlling a DC current of the non-sinusoidal voltage waveform. Thus, active tuning of the slope for different plasma densities is achieved. Additionally, a zero-current switched energy converter is used with the system to recover radio frequency (RF) energy stored in the plasma chamber. Multiple switches are connected to buses that are coupled to the system and are zero voltage switched. All this results in an exceptional power delivery efficiency of more than 85% to deliver a large amount of power, such as 30 kilowatts (kW), to the plasma chamber.

In an embodiment, multiple combined HV supplies are provided. When a voltage at an input of the plasma load is to be reduced, the RF energy stored in the plasma chamber is discharged. The discharge is carried out by an active magnetic energy recovery (MER) circuit, resulting in a tailored waveform HV output. The shape of the waveform can be modified by increasing or decreasing the output of the combination of HV supplies with respect to time. The discharge recovers the RF energy stored in the plasma chamber and feeds the RF energy at an input of the main power supply or the TES power supply.

In one embodiment, a combination of voltage supplies is provided to produce positive voltage pulses. Also provided is a separate function to enable energy recovery using a power converter. The power converter recovers RF energy from the plasma chamber and feeds the RF energy back to the input of the NSB power supply. A controllable current source enables a control of current drawn from the plasma chamber and compensates for the wafer charging due to the ion flux. By controlling the current drawn from the plasma chamber during the wafer charging phase, the wafer voltage is made flat resulting in narrow ion energy distribution.

In an embodiment, an integration of main and TES units of a power supply into one system is provided. The integration enables good coordination of the main and TES units, and thereby keeps the plasma sheath over a wafer coordinated with the plasma sheath over the edge ring. Without this coordination, the plasma sheath can wobble radially at an edge of the wafer, and such wobble can cause ellipticity in etched features as the ions follow an electric field from the wobble.

In an embodiment, a system for use with a plasma chamber is described. The plasma chamber has a substrate support and an edge ring surrounding the substrate support. The system includes a non-sinusoidal voltage waveform source, a first output of the non-sinusoidal voltage waveform source connected to the substrate support, and a second output of the non-sinusoidal voltage waveform source connected to the edge ring. The system includes a controller that controls the non-sinusoidal voltage waveform source to produce a first NSB waveform for the substrate support via the first output and a second NSB waveform for the edge ring via the second output. The first and second NSB waveforms provide pulsed biasing voltages to plasma generated in the plasma chamber.

In one embodiment, a system is described. The system includes a first power supply and a second power supply. The first power supply includes a first DC power source that generates a first DC voltage waveform, a first capacitor coupled in parallel to the first DC power source, and a first plurality of voltage supplies coupled to the first capacitor. The first plurality of voltage supplies receives the first DC voltage waveform to facilitate output of a first non-sinusoidal voltage waveform to a main electrode of a plasma chamber. The second power supply includes a second DC power source configured to generate a second DC voltage waveform, a second capacitor coupled in parallel to the second DC power source, and a second plurality of voltage supplies coupled to the second capacitor. The second plurality of voltage supplies receives the second DC voltage waveform to facilitate output of a second non-sinusoidal voltage waveform to an edge electrode of the plasma chamber. The system includes a controller coupled to the first and second pluralities of voltage supplies to control a plurality of amplitudes of the first and second non-sinusoidal voltage waveforms to achieve process rate uniformity at the substrate.

In an embodiment, a method is described. The method includes generating, by a first DC power source, a first DC voltage waveform, receiving the first DC voltage waveform to facilitate output of a first non-sinusoidal voltage waveform to a main electrode of a plasma chamber. The method includes generating, by a second DC power source a second DC voltage waveform, receiving the second DC voltage waveform to facilitate output of a second non-sinusoidal voltage waveform to an edge electrode of the plasma chamber. The method includes controlling a plurality of amplitudes of the first and second non-sinusoidal voltage waveforms to achieve process rate uniformity at the substrate.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of a system to illustrate a method for supplying non-sinusoidal radio frequency (RF) signals to a main electrode and to an edge electrode of a plasma chamber.

FIG. 2 is a diagram of an embodiment of a system to illustrate use of ion flux compensation associated with the main electrode and the edge electrode to control non-sinusoidal pulses of the non-sinusoidal voltage waveforms supplied to the main and edge electrodes.

FIG. 3 is a diagram of an embodiment of a system to illustrate use of a single clock source for synchronizing operation of main and tunable edge sheath (TES) power supplies.

FIG. 4 is an embodiment of a graph to illustrate that different plasma sheath voltages in a main region and an edge region of the plasma chamber are generated by the main and TES power supplies and the plasma sheath voltages are controlled to be substantially horizontal to achieve a flat sheath potential.

FIG. 5 is an embodiment of a system to illustrate details of a non-sinusoidal bias (NSB) supply having the main and TES power supplies.

FIG. 6 is an embodiment of a system to illustrate energy recovery by using a switch and a direct current (DC) voltage source.

FIG. 7 is an embodiment of a system to illustrate energy recovery by using a current source.

FIG. 8A is an embodiment of a system to illustrate use of a single control for achieving compensation for the ion flux and for achieving energy recovery.

FIG. 8B is an embodiment of graphs to illustrate operation of the system of FIG. 8A.

FIG. 9A is an embodiment of a system to illustrate use of an energy recovery circuit to recover RF energy stored in a stray capacitance of the plasma chamber.

FIG. 9B is an embodiment of a graph and another graph to illustrate operation of the system of FIG. 9A.

FIG. 10 is a diagram of an embodiment of a system to illustrate use of a voltage source system with a constant current source.

FIG. 11 is a diagram of an embodiment of a system to illustrate details of the system of FIG. 10.

FIG. 12 is an embodiment of a graph to illustrate a voltage generated by the NSB supply.

FIG. 13 is an embodiment of a system to illustrate a control of a DC power supply, a combination of high-voltage (HV) supplies, and an energy recovery circuit to achieve the predetermined sheath potential.

FIG. 14 is a diagram of an embodiment of an integrated combination of HV supplies.

### DETAILED DESCRIPTION

The following embodiments describe systems and methods for controlling main electrode and edge ring using non-sinusoidal radio frequency (RF) pulses to achieve process rate uniformity. It will be apparent that the present embodiments may be practiced without some or all of these specific details. In other instances, well known process operations have not been described in detail in order not to unnecessarily obscure the present embodiments.

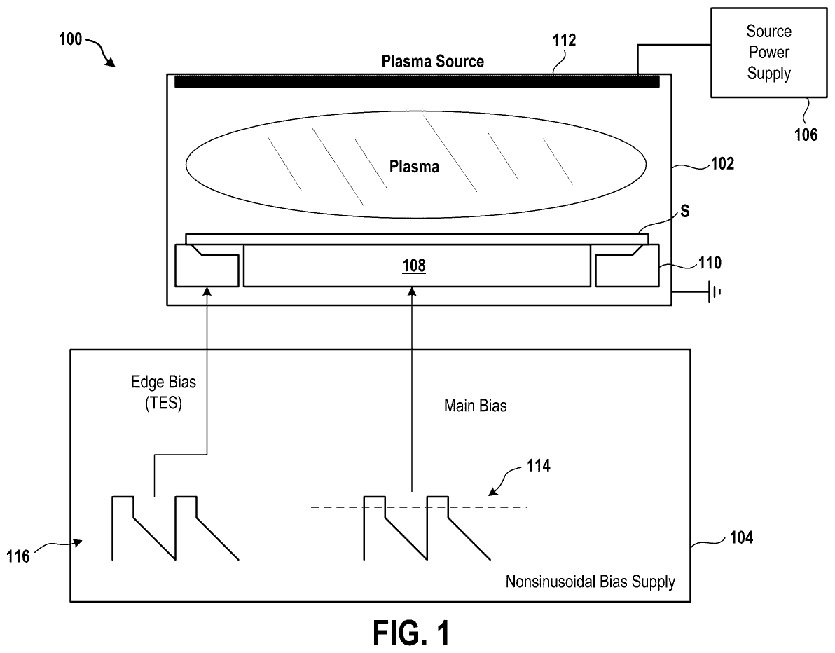

FIG. 1 is a diagram of an embodiment of a system 100 to illustrate a method for supplying non-sinusoidal voltage waveforms to a main electrode and to an edge electrode. The system 100 includes a plasma chamber 102 and a non-sinusoidal bias (NSB) supply 104. An NSB supply is sometimes referred to herein as a pulser or a nonsinusoidal voltage source. An example of the pulser is a nanopulser that generates one or more nanopulse voltage waveforms, and each nanopulse voltage waveform includes a series of nanopulses. As an example, the pulser generates at least one non-sinusoidal voltage waveform, and each non-sinusoidal voltage waveform has a frequency ranging from and including 400 kilohertz (kHz) to 1 megahertz (MHz). An example of the plasma chamber 102 is a capacitively coupled plasma (CCP) chamber. The system 100 further includes a source power supply 106. An example of the source power supply 106 is a 2 MHz power supply or a 13.56 MHz power supply or a 60 MHz power supply or a 400 kHz power supply.

The plasma chamber 102 includes the main electrode embedded within an electrostatic chuck (ESC) 108 and an edge ring 110, which is an example of the edge electrode. The edge ring 110 surrounds the ESC 108. For example, the edge ring 110 encircles the ESC 108.

The source power supply 106 is coupled to a top electrode 112 of the plasma chamber 102. The NSB supply 104 is coupled to the ESC 108 and the edge electrode 110.

The source power supply 106 generates and supplies an RF signal to the top electrode 112 of the plasma chamber 102. When one or more process gases are supplied to the plasma chamber 102 in conjunction with the RF signal supplied to the top electrode 112, plasma is generated within the plasma chamber 102.

Moreover, the NSB supply 104 facilitates output of multiple non-sinusoidal voltage waveforms including a main non-sinusoidal voltage waveform 114 and a TES non-sinusoidal voltage waveform 116. As an example, each non-sinusoidal voltage waveform 114 and 116 is a 400 kHz signal. The NSB supply 104 facilitates output of the main non-sinusoidal voltage waveform 114 to the ESC 108 and facilitates output of the TES non-sinusoidal voltage waveform 116 to the edge electrode 110.

The main non-sinusoidal voltage waveform 114 is provided to the main electrode to provide a pulsed biasing voltage to the main electrode and TES non-sinusoidal voltage waveform 116 is provided to the edge electrode 110 to provide a pulsed biasing voltage to the edge electrode 110. The pulsed biasing voltages are provided to enable attraction of ions of plasma that is generated by the RF signal supplied to the top electrode 112. The ions are used to process a substrate S, such as a semiconductor wafer, that is placed on top of ESC 108.

In one embodiment, the top electrode 112 is coupled to a ground potential.

In an embodiment, the source power supply 106 is coupled to the main electrode and the top electrode 112 is coupled to the ground potential.

In an embodiment, instead of the CCP chamber, an inductively coupled plasma (ICP) chamber is used. In the ICP chamber, instead of the top electrode 112, such as a plate electrode, one or more top coils are used. The one or more top coils are an example of an electrode.

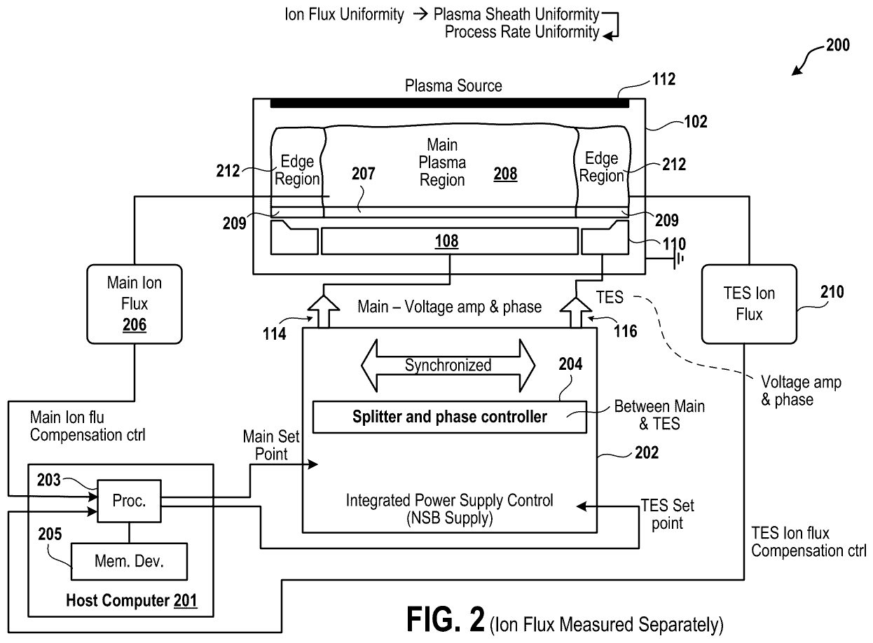

FIG. 2 is a diagram of an embodiment of a system 200 to illustrate use of ion flux compensation associated with the main electrode and the edge electrode 110 to generate non-sinusoidal pulses of the non-sinusoidal voltage waveforms 114 and 116 for supplying to the main and edge electrodes 108 and 110.

The system 200 includes an NSB supply 202, which is an example of the NSB supply 104 (FIG. 1). The NSB supply 202 includes a splitter and phase controller 204. The splitter and phase controller 204 controls a phase relationship between the non-sinusoidal voltage waveforms 114 and 116. For example, the splitter and phase controller 204 controls the non-sinusoidal voltage waveforms 114 and 116 to be in phase with each other or to be out of phase with each other by a predetermined phase difference to synchronize the non-sinusoidal voltage waveforms 114 and 116.

The system 200 further includes a host computer 201. An example of the host computer 201 includes a desktop computer or a laptop computer or a smart phone or a tablet or a controller. The host computer 201 includes a processor 203 and a memory device 205. Examples of a processor, as used herein, include a central processing unit (CPU) and a microprocessor. Examples of a memory device include a random access memory, a read-only memory, and a combination thereof. Examples of a controller, as used herein, include a combination of one or more processors and one more memory devices. The one or more processors are coupled to the one or more memory devices. The processor 203 is coupled to the NSB supply 202.

The processor 203 provides a main set point and a TES set point to the NSB supply 202. An example of the main set point is a maximum amplitude of voltage of the main non-sinusoidal voltage waveform 114. An example of the TES power set point is a maximum amplitude of voltage of the TES non-sinusoidal voltage waveform 116.

Also, a main ion flux control circuit 206 is coupled to the plasma chamber 102 and the processor 203 to control the main non-sinusoidal voltage waveform 114 to achieve a predetermined amount of compensation for main ion flux. The main ion flux is ion flux in a main region 208, of the plasma chamber 102, above the main electrode 108. For example, a main ion flux probe is placed within the main region 208 and the amount of main ion flux is sensed by a main ion flux sensor. Based on the amount of main ion flux, the processor 203 controls the NSB supply 202 to further control the main non-sinusoidal voltage waveform 114 to achieve the predetermined amount of compensation for main ion flux. As another example, there is no use of the main ion flux probe and the main ion flux sensor. Rather, during processing of the substrate S, the processor 203 controls the NSB supply 202 to facilitate output of the main non-sinusoidal voltage waveform 114 to achieve the predetermined amount of compensation for main ion flux. In the example, the predetermined amount of compensation for main ion flux is determined experimentally or is estimated by the processor 203 before processing of the substrate S.

Similarly, a TES ion flux control circuit 210 is coupled to the plasma chamber 102 and the processor 203 to control the TES non-sinusoidal voltage waveform 116 to achieve a predetermined amount of compensation for TES ion flux, which is ion flux in an edge region 112, of the plasma chamber 102, above the edge ring 110. For example, a TES ion flux probe is placed within the edge region 112 and the amount of TES ion flux is sensed by a TES ion flux sensor. Based on the amount of TES ion flux, the processor 203 controls the NSB supply 202 to further control the TES non-sinusoidal voltage waveform 116 to achieve the predetermined amount of compensation for TES ion flux. As another example, there is no use of the TES ion flux probe and the TES ion flux sensor. Rather, during processing of the substrate S, the processor 203 controls the NSB supply 202 to facilitate output of the TES non-sinusoidal voltage waveform 116 to achieve the predetermined amount of compensation for TES ion flux. In the example, the predetermined amount of compensation for TES ion flux is determined experimentally or is estimated by the processor 203 before processing of the substrate S.

The main ion flux is flux of ions in the main region 208 (FIG. 2) and the TES ion flux is flux of ions in the edge region 212 of the plasma chamber 102. The edge region 212 surrounds the main region 208 and is closer to an edge of the substrate S compared to the main region 208. The main region 208 is proximate to a central portion of the substrate S compared to the edge region 212.

An example of an ion flux control circuit includes a combination of an ion flux probe and an ion flux sensor. To illustrate, the ion flux probe is a Langmuir probe the generates a measured amount of current based on a measured amount of ion flux that interfaces with the Langmuir probe and the ion flux sensor determines the measured amount of ion flux based on the measured amount of current based on correspondences between amounts of currents and amounts of ion fluxes.

The processor 203 is coupled to the main ion flux control circuit 206 and the TES ion flux control circuit 210. The processor 203 receives the amount of main ion flux from the main ion flux control circuit 206 and receives the amount of TES ion flux from the TES ion flux control circuit 210, controls the NSB supply 202 to further control an amplitude, such as the maximum amplitude, of voltage of the main non-sinusoidal voltage waveform 114, and controls the NSB supply 202 to further control an amplitude, such as the maximum amplitude, of voltage of the TES non-sinusoidal voltage waveform 116. For example, the processor 203 increases or decreases the amplitude of voltage of the main non-sinusoidal voltage waveform 114 or increases or decreases the amplitude of voltage of the TES non-sinusoidal voltage waveform 116 until the amount of TES ion flux is compensated to be within a predetermined range, such as equal to, from a compensation of the amount of main ion flux. The predetermined range is stored within the memory device 205 for access by the processor 203.

When the amount of TES ion flux is compensated to be within the predetermined range from the compensation of the amount of main ion flux, plasma sheath uniformity is achieved between a portion 207 of a lower plasma sheath and a portion 209 of the lower plasma sheath. The portion 207 is adjacent to, such as adjoining to or contiguous with, the main region 208 and is located between the main region 208 and the ESC 108. The portion 209 is adjacent to, such as adjoining to or contiguous with, the edge region 212 and is located between the edge region 212 and the edge ring 209. When the plasma sheath uniformity is achieved, a process rate uniformity, such as an etch rate uniformity, or a deposition rate uniformity or a combination thereof, for processing the substrate S is achieved.

In one embodiment, the main ion flux control circuit 206 also provides energy recovery, which is described below. Similarly, the TES ion flux control circuit 210 provides energy recovery described below.

In an embodiment, the NSB supply 202 includes a single direct current (DC) source that generates a DC voltage waveform. As used herein, an example of a DC source is a DC voltage source or a DC power source. The DC voltage waveform generated by the DC source is split by a splitter of the NSB supply 202 into two DC voltage waveforms and a respective one of the two DC voltage waveforms is provided to a respective one of two sets of high voltage (HV) supplies of the NSB supply 202. A first one of the two sets of HV supplies facilitates output of the main non-sinusoidal voltage waveform 114 and a second one of the two sets of HV supplies facilitates output of the TES non-sinusoidal voltage waveform 116. As an example, each HV supply, described herein, converts an amplitude of voltage of a DC voltage waveform received from the splitter into another amplitude of voltage to output a modified DC voltage waveform. To illustrate, an HV supply converts a first amplitude of voltage into a second amplitude of voltage. The second amplitude is greater than the first amplitude or less than the first amplitude. The modified DC voltage waveform is transferred via a resonant inductor to generate a non-sinusoidal voltage waveform, such as the main non-sinusoidal voltage waveform 114 or the TES non-sinusoidal voltage waveform 116.

In one embodiment, an application specific integrated circuit (ASIC), or a programmable logic device (PLD) is used to perform the same operations that are described herein as being performed by a processor.

In an embodiment, the splitter and phase controller 204 is a part of the host computer 201.

In one embodiment, the terms power source and voltage source are used herein interchangeably.

In an embodiment, the terms power supply and voltage supply are used herein interchangeably.

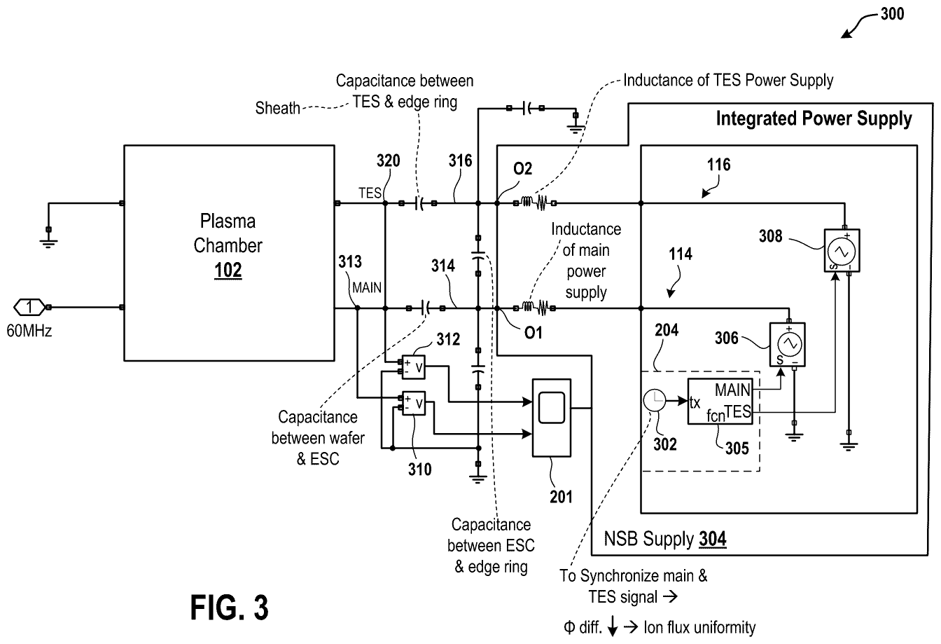

FIG. 3 is a diagram of an embodiment of a system 300 to illustrate a single clock source 302 within an NSB supply 304 for synchronizing operation of main and tunable edge sheath (TES) power supplies. The NSB supply 304 is an example of the NSB supply 104 or 202 (FIGS. 1 & 2). The NSB supply 304 includes a signal controller 305, a main power supply 306, and a TES power supply 308. The clock source 302 and the signal controller 305 are components of the splitter and phase controller 204. The signal controller 305 is coupled to the processor 203 (FIG. 2) for receiving the main and TES setpoints from the processor 203.

The main power supply 306 is coupled to the main electrode of the plasma chamber 102 via an output O1 and an RF connection 314. An example of the output O1 is a connector of the NSB supply 304. The RF connection 314 is coupled to the output O1 and to the main electrode. Also, the TES power supply 308 is coupled to the edge ring 110 of the plasma chamber 102 via an output O2 and an RF connection 316. An example of the output O2 is a connector of the NSB supply 304. The RF connection 316 is coupled to the output O2 and to the edge ring 110. An example of an RF connection includes one or more RF straps that are coupled to each other in series.

The clock source 302 generates and supplies a clock signal to the signal controller 305 to synchronize operation of the main power supply 306 and the TES power supply 308. For example, in synchronization with the clock signal, the signal controller 305 outputs a main control signal and sends the main control signal to the main power supply 306 and the signal controller 305 outputs a TES control signal and sends the TES control signal to the TES power supply 308. To illustrate, when the clock signal transitions from a low logic level to a high logic level at a first time, the signal controller 305 outputs the main and TES control signals. In the illustration, when the clock signal transitions from the low logic level to the high logic level at a second time, the signal controller 305 outputs the main and TES control signals again. The second time is consecutive to the first time in that there is no instance of a transition from the low logic level to the high logic level between the first and second times. As an example, the main control signal indicates a phase or voltage amplitude, such as the maximum amplitude, or a combination thereof of the main non-sinusoidal voltage waveform 114. As an example, the TES control signal indicates a phase or voltage amplitude, such as the maximum amplitude, or a combination thereof of the TES non-sinusoidal voltage waveform 116.

The main power supply 306 facilitates output of the main non-sinusoidal voltage waveform 114 based on the main control signal and the TES power supply 308 facilitates output of the TES non-sinusoidal voltage waveform 116 based on the TES control signal. For example, the main power supply 306 facilitates output of the main nonsinusoidal voltage waveform 114 at a time the main control signal is received and the TES power supply 308 facilitates output of the TES non-sinusoidal voltage waveform 160 at a time the TES control signal is received. The main non-sinusoidal voltage waveform 114 is produced to achieve the maximum amplitude of voltage indicated within the main control signal and the TES non-sinusoidal voltage waveform 116 is produced to achieve the maximum amplitude, of voltage indicated within the TES control signal.

When both the main and TES non-sinusoidal voltage waveforms 114 and 116 are synchronized with the clock signal, phases of the main and TES non-sinusoidal voltage waveforms 114 and 116 are controlled to be within a predetermined range from each other. For example, phases of both the main and TES non-sinusoidal voltage waveforms 114 and 116 are equal to each other. When the phases of the main and TES non-sinusoidal voltage waveforms 114 and 116 are controlled to be within the predetermined range, the process rate uniformity is achieved between the main region 208 (FIG. 2) and the edge region 212 (FIG. 2).

In one embodiment, instead of an ion flux sensor and an ion flux probe, a voltage sensor is used to determine ion flux. For example, a main voltage sensor 310 is coupled at a point 318 on the RF connection 314 and is coupled to the processor 203 (FIG. 2) of the host computer 201. Similarly, a TES voltage sensor 312 is coupled at a point 320 on the RF connection 316 and is coupled to the processor 203. The main voltage sensor 310 measures a voltage at the point 318 to generate a main measurement signal and provides the main measurement signal to the processor 203. The main measurement signal represents ion flux within the main region 208 (FIG. 2). For example, the main measurement signal includes a main V&I measurement, such as a main voltage amplitude and a main current amplitude and a phase between the main voltage amplitude and the main current amplitude. Also, the TES voltage sensor 312 measures a voltage at the point 320 to generate a TES measurement signal and provides the TES measurement signal to the processor 203. The TES measurement signal represents ion flux within the edge region 212 (FIG. 2). For example, the TES measurement signal includes a TES V&I measurement, such as a TES voltage amplitude and a TES current amplitude and a phase between the TES voltage amplitude and the TES current amplitude.

In the embodiment, the processor 203 receives the main and TES measurement signals and determines a main ion flux corresponding to the main measurement signal and a TES ion flux corresponding to the TES measurement signal. For example, the processor 203 accesses a table stored within the memory device 205 (FIG. 2) including correspondences between amounts of ion fluxes and V&I measurements, to determine the main and TES ion fluxes. To illustrate, one of the amounts of V&I measurements stored in the memory device 205 matches the main V&I measurement and corresponds to, such as has a one-to-one relationship with, one of the amounts of ion fluxes. The processor 203 determines that the one of amount of ion fluxes is the main ion flux. As another illustration, one of the amounts of V&I measurements stored in the memory device 205 matches the TES V&I measurement and corresponds to, such as has a one-to-one relationship with, one of the amounts of ion fluxes. The processor 203 determines that the one of amount of ion fluxes is the TES ion flux.

Further in the embodiment, the processor 203 controls the main power supply 306 or the TES power supply 308 or both the power supplies 306 and 308 until an amount of main ion flux determined from a main measurement signal is compensated to be within a predetermined range, such as equal to, from a compensation of an amount of TES ion flux determined from a TES measurement signal. For example, the processor 203 modifies, such as increases or decreases, the maximum amplitude of the main non-sinusoidal voltage waveform 114, of the main setpoint to generate a modified main setpoint, and sends the modified main setpoint to the signal controller 305. Upon receiving the modified main setpoint, the signal controller 305 controls the main power supply 306 to modify the maximum amplitude of voltage of the main nonsinusoidal voltage waveform 114. As another example, the processor 203 modifies, such as increases or decreases, the maximum amplitude of the TES non-sinusoidal voltage waveform 116, of the TES setpoint to generate a modified TES setpoint and sends the modified TES setpoint to the signal controller 305. Upon receiving the modified TES setpoint, the signal controller 305 controls the TES power supply 308 to modify the maximum amplitude of voltage of the TES non-sinusoidal voltage waveform 116.

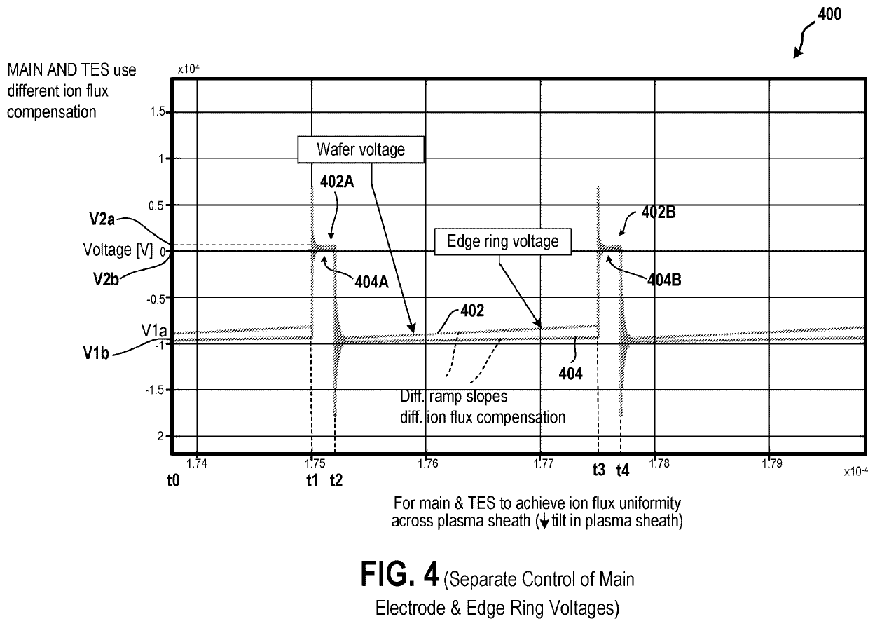

FIG. 4 is an embodiment of a graph 400 to illustrate that different plasma sheath voltages in the main region 208 and the edge region (FIG. 2) are generated by the non-sinusoidal voltage waveforms 114 and 116 produced by the main and TES power supplies 306 and 308 (FIG. 3), and the plasma sheath voltages are controlled separately to achieve the process rate uniformity. The graph 400 plots voltage on a y-axis and time t on an x-axis. The time t includes times t0, t1, t2, t3, and t4 in succession. For example, the time t1 occurs after the time to, the time t2 occurs after the time t1, the time t3 occurs after the time t2, and the time t4 occurs after the time t3.

The graph 400 includes a voltage waveform 402 and another voltage waveform 404. As an example, the voltage waveform 402 is an example of the main non-sinusoidal voltage waveform 114 (FIG. 1) and the voltage waveform 404 is an example of the TES nonsinusoidal voltage waveform 116 (FIG. 1). As another example, the voltage waveform 402 represents voltage of a plasma sheath in the main region 208 and the voltage waveform 404 represents voltage of the plasma sheath in the edge region 212.

The voltage waveform 402 has multiple pulses 402A and 402B. For example, the pulse 402A occurs from the time t1 to the time t2 and transitions from a low voltage level, such as V1a, to a high voltage level, such as V2a, and further transitions from the high voltage level to the low voltage level. As another example, the pulse 402B occurs from the time t3 to the time t4 and transitions from the low voltage level, such as V1a, to the high voltage level, such as V2a, and further transitions from the high voltage level to the low voltage level. To illustrate, the high voltage level V2a includes voltage amplitudes that are exclusive from voltage amplitudes of the low voltage level V1a and the high voltage level V2a is greater than the low voltage level V1a. As another illustration, the high voltage level V2a is an example of the maximum amplitude, of voltage of the voltage waveform 402.

Similarly, the voltage waveform 404 has multiple pulses 404A and 404B. For example, the pulse 404A occurs from the time t1 to the time t2 and transitions from a low voltage level, such as V1b, to a high voltage level, such as V2b, and further transitions from the high voltage level to the low voltage level. As another example, the pulse 404B occurs from the time t3 to the time t4 and transitions from the low voltage level, such as V1b, to the high voltage level, such as V2b, and further transitions from the high voltage level to the low voltage level. As an illustration, the high voltage level V2b includes voltage amplitudes that are exclusive from voltage amplitudes of the low voltage level V1b and the high voltage level V2b is greater than the low voltage level V1b. To illustrate, the high voltage level V2b is an example of the maximum amplitude, of voltage of the voltage waveform 404.

Each pulse of the voltage waveform 402 or 404 occurs during a cycle of the clock signal. For example, the pulse 402A occurs during a first cycle of the clock signal, and the pulse 402B occurs during a second cycle of the clock signal. The second cycle is consecutive to the first cycle.

The processor 203 (FIG. 2) controls a parameter, such as a ramp slope or the maximum amplitude or a combination thereof, of the non-sinusoidal voltage waveform 114 or 116 or controls the parameters of both the non-sinusoidal voltage waveforms 114 and 116, to control the voltage waveforms 402 and 404. For example, a positive slope of the voltage waveform 402 between the time t2 and the time t3 of the time t is reduced to match a substantially zero slope, such as a zero slope, of the voltage waveform 404 between the times t2 and t3. As another example, positive slopes of the voltage waveforms 402 and 404 are reduced between the times t2 and t3 to achieve the substantially zero slope, such as the zero slope, to achieve the process rate uniformity. By controlling the parameters, ion flux uniformity between the main region 208 and the edge region 212 is achieved. When the ion flux uniformity is achieved, tilt between the portions 207 and 209 (FIG. 2) of the lower plasma sheath is reduced. As yet another example, the parameter of the non-sinusoidal voltage waveform 114 or 116 or the parameters of the non-sinusoidal voltage waveforms 114 and 116 are controlled to achieve the positive slope of the voltage waveform 402 between the times t2 and t3 and the substantially zero slope of the voltage waveform 404 between the times t2 and t3.

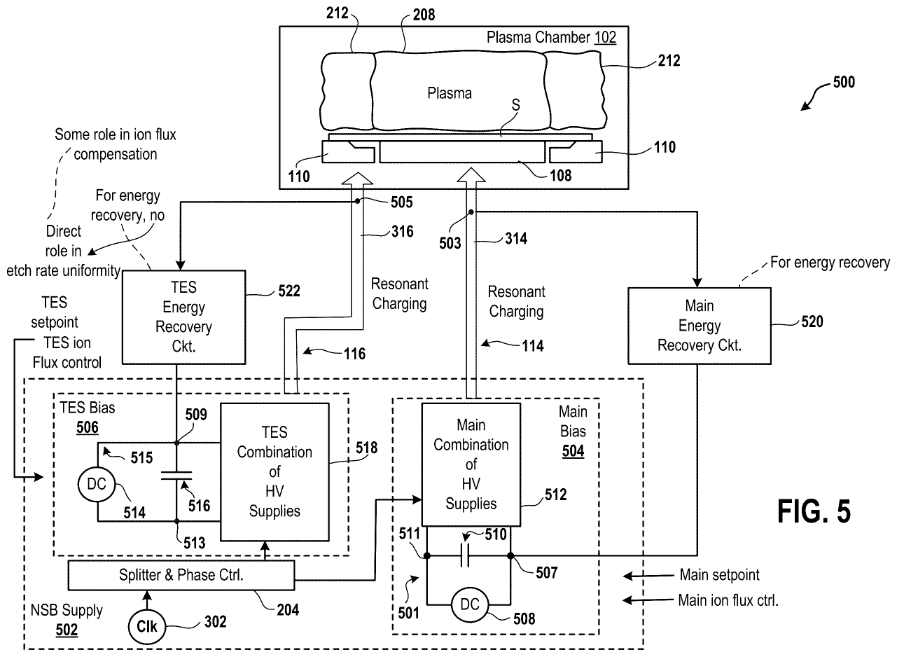

FIG. 5 is an embodiment of a system 500 to illustrate details of a non-sinusoidal bias (NSB) supply 502 having main and TES power supplies. The NSB supply 502 is an example of the NSB supply 104 (FIG. 1), or 202 (FIG. 2), or 304 (FIG. 3). The NSB supply 502 includes a main power supply 504 and a TES power supply 506. The main power supply 504 is an example of the main power supply 306 (FIG. 3) and the TES power supply 506 is an example of the TES power supply 308 (FIG. 3). The NSB supply 502 also includes the clock source 302 and the splitter and phase controller 204.

The main power supply 504 includes a main DC source 508, a main capacitor 510 in parallel with the main DC source 508, and a main combination 512 of HV supplies in parallel with the main DC source 508 and the main capacitor 510. For example, each of the main DC source 508, the main capacitor 510, and the main combination 512 is coupled in parallel between points 507 and 511. To illustrate, a voltage across each of the main DC source 508, the main capacitor 510, and the main combination 512 is equal. Similarly, the TES power supply 506 includes a TES DC source 514, a TES capacitor 516 in parallel with the TES DC source 514, and a TES combination 518 of HV supplies in parallel with the TES DC source 514 and the TES capacitor 516. For example, each of the TES DC source 514, the TES capacitor 516, and the TES combination 518 is coupled in parallel between points 509 and 513. To illustrate, a voltage across each of the TES DC source 514, the TES capacitor 516, and the TES combination 518 is equal. As an example, a DC source, as described herein, is a voltage source or a power source.

The splitter and phase controller 204 is coupled to the main combination 512 and the TES combination 518. The main combination 504 is coupled via the RF connection 314 to the main electrode of the ESC 108 and the TES combination 518 is coupled via the RF connection 316 to the edge ring 110.

Also, the system 500 includes a main energy recovery circuit 520 and a TES energy recovery circuit 522. The main energy recovery circuit 520 is coupled at a point 503 on the RF connection 314 and the TES energy recovery circuit 522 is coupled at a point 505 on the RF connection 316. Also, the main energy recovery circuit 520 is coupled to the main capacitor 510 at the point 507 and the TES energy recovery circuit 522 is coupled at the point 509 to the TES capacitor 516.

The main DC source 508 generates a main DC voltage waveform 501 and supplies the main DC voltage waveform 501 to the main combination 512. The main combination 512 facilitates output of the main non-sinusoidal voltage waveform 114 based on a voltage of the main DC voltage waveform 501 and the main non-sinusoidal voltage waveform 114 is supplied for resonant charging of the main region 208 to the main electrode of the ESC 108. For example, the signal controller 305 (FIG. 3) of the splitter and phase controller 204 provides the main control signal to the main combination 512. In the example, upon receiving the main control signal, one or more of the HV supplies of the main combination 512 are activated, such as enabled, or deactivated, such as disabled, to modify a voltage of the main DC voltage waveform 501 to further modify a voltage of main non-sinusoidal voltage waveform 114 to achieve the maximum amplitude indicated in the main control signal. In the example, the voltage of the main DC voltage waveform 501 is modified to output a modified main DC voltage waveform 517 from the main combination 512. The modified main DC voltage waveform 517 is converted to the main non-sinusoidal voltage waveform 114 by a main diode and a main resonant inductor. The main diode and the main resonant inductor are coupled between the main combination 512 and the main electrode. The main diode is connected to the main combination 512 at one end and is coupled to the main resonant inductor via a main switch at an opposite end. The main resonant inductor is coupled via a main blocking capacitor to the main electrode.

To further illustrate, from a total of 10 HV supplies of the main combination 512, two of the HV supplies are controlled by signal controller 305 to be coupled to the main DC source 508 and the RF connection 314 and the remaining eight of the HV supplies are controlled by the splitter and phase controller 204 to be decoupled from the main DC source 508 or the RF connection 314 are both. The voltage of the main DC voltage waveform 501 and the voltage of the main non-sinusoidal voltage waveform 114 increases with an increase in the number of HV supplies of the main combination 512 that are coupled to the main DC source 508 and the RF connection 314. On the other hand, the voltage of the of the main DC voltage waveform 501 and the voltage of the main non-sinusoidal voltage waveform 114 decreases with a decrease in a number of HV supplies of the main combination 512 that are coupled to the main DC source 508 and the RF connection 314. In the example, the one or more of the HV supplies of the main combination 512 are activated or deactivated to modify a voltage of the main DC voltage waveform 501 to output the voltage of the main non-sinusoidal voltage waveform 114.

The TES DC source 514 generates a TES DC voltage waveform 515 and supplies the TES DC voltage waveform 515 to the TES combination 518. The TES combination 518 facilitates output of the TES non-sinusoidal voltage waveform 116 based on the TES DC voltage waveform 515 and the TES non-sinusoidal voltage waveform 116 is supplied for resonant charging of the edge region 212 to the edge ring 110. As an example, the signal controller 305 provides the TES control signal to the TES combination 518. In the example, upon receiving the TES control signal, one or more of the HV supplies of the TES combination 518 are activated, such as enabled, or deactivated, such as disabled, to modify a voltage of the TES DC voltage waveform 515 and the TES non-sinusoidal voltage waveform 116 to achieve the maximum amplitude indicated in the TES control signal. In the example, the voltage of the TES DC voltage waveform 515 is modified to output a modified TES DC voltage waveform 519 from the TES combination 518. The modified TES DC voltage waveform 519 is converted to the TES non-sinusoidal voltage waveform 116 by a TES diode and a TES resonant inductor. The TES diode and the TES resonant inductor are coupled between the TES combination 518 and the edge ring 110. The TES diode is connected to the TES combination 518 at one end and is coupled to the TES resonant inductor via a TES switch at an opposite end. The TES resonant inductor is coupled via a TES blocking capacitor to the edge ring 110.

To further illustrate, from a total of 15 HV supplies of the TES combination 518, ten of the HV supplies are controlled by the signal controller 305 to be coupled to the TES DC source 514 and the RF connection 316 and the remaining five of the HV supplies are controlled by the splitter and phase controller 204 to be decoupled from the TES DC source 514 or the RF connection 316 are both. The voltage of the TES DC voltage waveform 515 and the voltage of the TES non-sinusoidal voltage waveform 116 increases with an increase in the number of HV supplies of the TES combination 512 that are coupled to the TES DC source 514 and the RF connection 316. On the other hand, the voltage of the TES DC voltage waveform 515 and the voltage of the TES non-sinusoidal voltage waveform 116 decreases with a decrease in a number of HV supplies of the TES combination 518 that are coupled to the TES DC source 514 and the RF connection 316. In the example, the one or more of the HV supplies of the TES combination 518 are activated or deactivated to modify a voltage of the TES DC voltage waveform 515 to output the voltage of the TES non-sinusoidal voltage waveform 116.

The main combination 512 generates the modified main DC voltage waveform 517 to facilitate an output of the main non-sinusoidal voltage waveform 114 and the main non-sinusoidal voltage waveform 114 is supplied to the main electrode. As an example, one or more resonant inductors, such as one or more inductors, or parasitic inductance, or stray inductance, coupling the main combination 512 to the main electrode provides the resonant charging to the main electrode from the main combination 512. To illustrate, there is no cable, such as a long cable, that couples the main combination 512 to the main electrode. Also, the TES combination 518 generates the modified TES DC voltage waveform 519 to facilitate an output of the TES non-sinusoidal voltage waveform 116 and the TES non-sinusoidal voltage waveform 116 is supplied to the edge ring 110. As an example, one or more resonant inductors, such as one or more inductors, or parasitic inductance, or stray inductance, coupling the TES combination 518 to the edge ring 110 provides the resonant charging to the edge ring 110 from the TES combination 518. To illustrate, there is no cable, such as a long cable, that couples the TES combination 518 to the edge ring 110.

The main energy recovery circuit 520 recovers main RF energy from the main region 208 and stores the main RF energy within the capacitor 510. The main RF energy is then used from the capacitor 510 by the main power supply 504 to generate a voltage of the main DC voltage waveform 501 to further output a voltage of the main non-sinusoidal voltage waveform 114. For example, a voltage across the main DC source 508 increases when there is an increase in a voltage across the capacitor 510. In the example, the voltage across the capacitor 510 increases from the RF energy that is recovered. Further, in the example, the processor 203 (FIG. 2) controls, such as enables or disables, one or more of the HV supplies of the main combination 512 to modify the voltage of the main DC voltage waveform 501 to further change a voltage of the modified main DC voltage waveform 517 output from the main combination 512 to change a voltage of the main non-sinusoidal voltage waveform 114.

Similarly, the TES energy recovery circuit 522 recovers TES RF energy from the edge region 212 and stores the TES RF energy within the capacitor 516. The TES RF energy is then used from the capacitor 516 by the TES power supply 506 to generate a voltage of the TES DC voltage waveform 515 to further output a voltage of the TES non-sinusoidal voltage waveform 116. For example, a voltage across the TES DC source 514 increases when there is an increase in a voltage across the capacitor 516. In the example, the voltage across the capacitor 516 increases from the RF energy that is recovered from the edge region 212. Further, in the example, the processor 203 (FIG. 2) controls, such as enables or disables, one or more of the HV supplies of the TES combination 518 to modify the voltage of the TES DC voltage waveform 515 to further modify a voltage of the TES modified TES DC voltage waveform 519 output from the TES combination 518 to change a voltage of the TES non-sinusoidal voltage waveform 116.

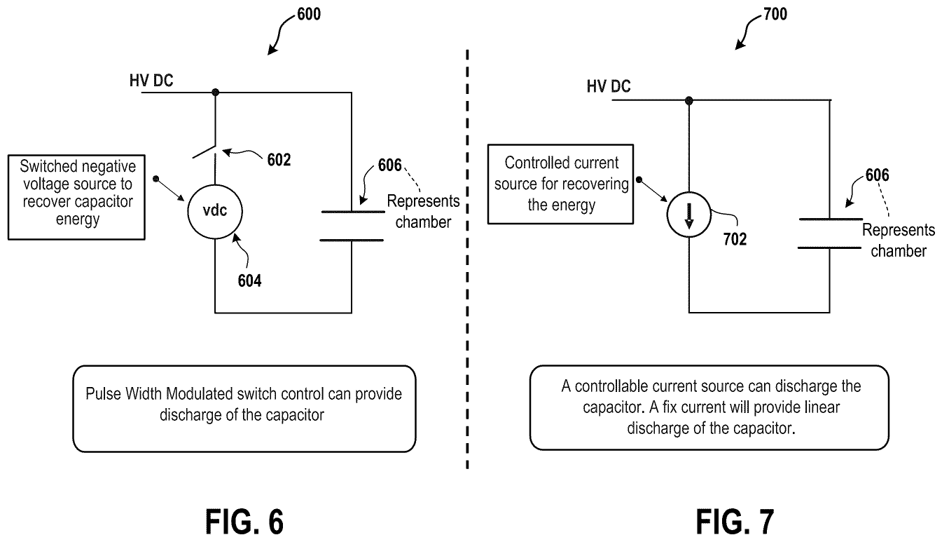

FIG. 6 is an embodiment of a system 600 to illustrate energy recovery by using a switch 602 and a direct current (DC) voltage source Vdc, which is illustrated as an energy recovery circuit 604. The energy recovery circuit 604 is an example of the energy recovery circuit 520 or 522 (FIG. 5). An example of a switch, as described herein, includes one or more transistors. To illustrate, the switch includes a single transistor or multiple transistor coupled to each other in series. A capacitor 606 of the system 600 represents a capacitance of the plasma chamber 102. The switch 602 is controlled by the processor 203 (FIG. 2) to discharge the capacitor 606 and store the RF energy recovered from the capacitor 706 into the energy recovery circuit 604.

In an embodiment, a diode is coupled in series with the switch 602 and the energy recovery circuit 604. For example, the diode is coupled between the switch 602 and the energy recovery circuit 604.

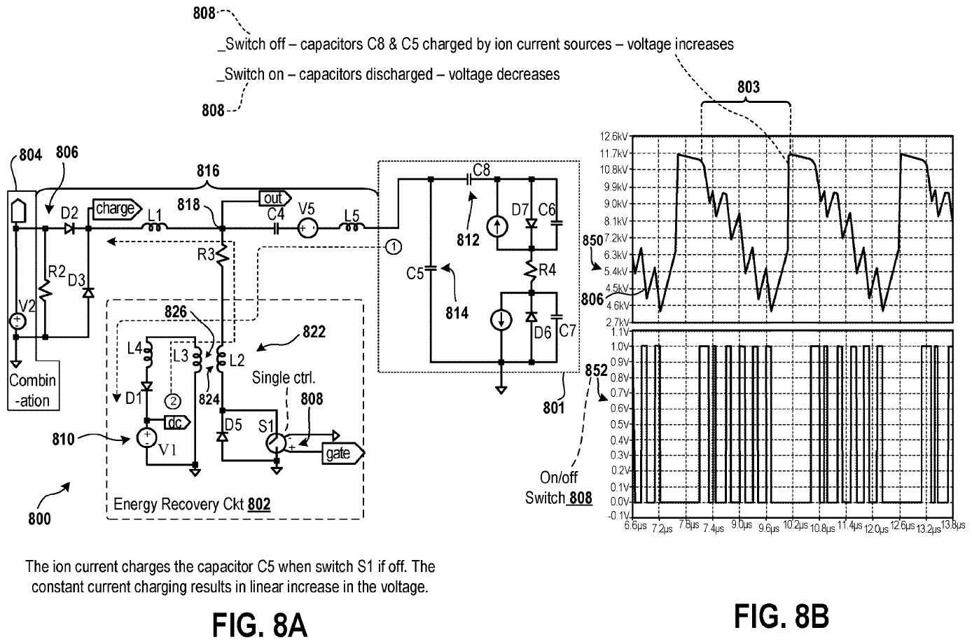

FIG. 7 is an embodiment of a system 700 to illustrate energy recovery by using a current source 702. The current source 702 is controlled by the processor 203 (FIG. 2) to discharge the RF energy from the capacitor 606 and transfer the recovered RF energy into the capacitor 510 or 516 (FIG. 5).

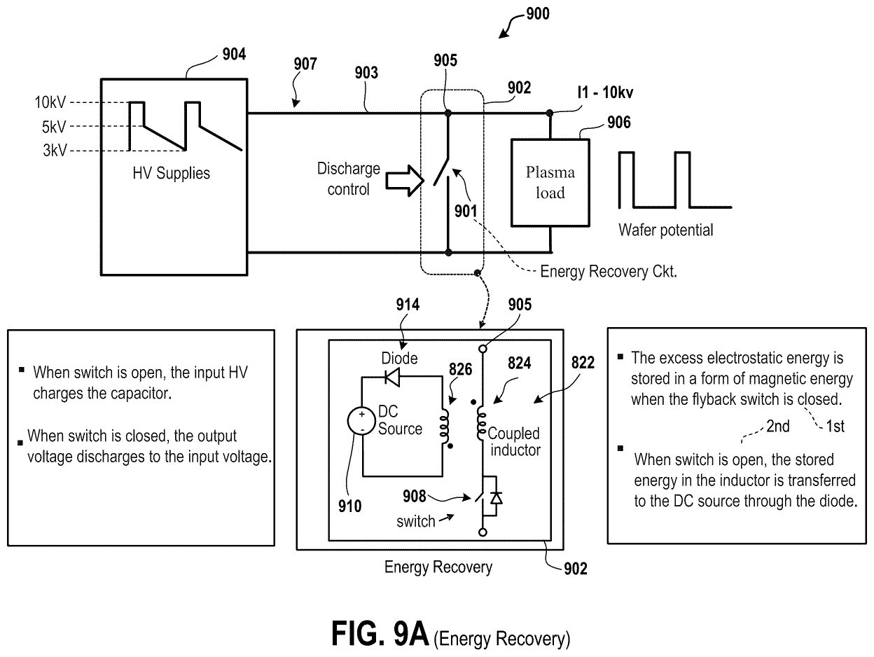

FIG. 8A is an embodiment of a system 800 to illustrate use of a single control for ion flux compensation and energy recovery to achieve the process rate uniformity. The system 800 includes an energy recovery circuit 802 and a nonlinear load 801. The nonlinear load 801 is an example of, such as a triode model of, the plasma chamber 102 (FIG. 1). The nonlinear load 801 includes current sources I1 and I2 to illustrate ion flux of plasma within the plasma chamber 102.

The energy recovery circuit 802 is an example of the main energy recovery circuit 520 (FIG. 5) or the TES energy recovery circuit 522 (FIG. 5). The energy recovery circuit 802 includes a switch 808 and a voltage source 810. An example of the voltage source 810 is the main capacitor 510 or the TES capacitor 516 (FIG. 5). To illustrate, the voltage source 810 represents a voltage across the main DC source 508 (FIG. 5) and the voltage is the same as that across the main capacitor 510. As another illustration, the voltage source 810 represents a voltage across the TES DC source 514 (FIG. 5) and the voltage is the same as that across the TES capacitor 516. The system 800 further includes a combination 804 of HV supplies. The combination 804 of HV supplies is an example of the main combination 512 or the TES combination 518 (FIG. 5).

The system 800 includes an RF connection 816 between the combination 804 and the nonlinear load 801. The combination 804 is coupled to the nonlinear load 801 via the RF connection 816, which includes a diode 805 and an inductor 807. The RF connection 816 is an example of any of the RF connections 314 and 316 (FIG. 3).

The energy recovery circuit 802 includes a transformer 822, which includes a first inductor 824, such as a coil, and a second inductor 826, such as a coil. The energy recovery circuit 802 includes the voltage source 810 that is connected to the second inductor 826. The energy recovery circuit 802 is coupled at a point 818 on the RF connection 816. For example, the first inductor 824 is coupled to the point 818. The switch 808 is coupled to the processor 203 (FIG. 2).

The processor 203 (FIG. 2) charges the nonlinear load 801 and, after the nonlinear load 801 is charged, the processor 203 controls the switch 808 to recover RF energy from the nonlinear load 801. Also, to charge the nonlinear load 801, the processor 203 controls the switch 808 to be off, such as open. For example, the processor 203 sends an off control signal to the switch 808 to turn off the switch 808. To charge the nonlinear load 801, the processor 203 provides a set point, such as the main set point or the TES set point, to the combination 804. Upon receiving the set point, the combination 804 outputs a DC voltage waveform 806 and sends the DC voltage waveform 806 to a circuit having the diode 805 and the inductor 807. The diode 805 and the inductor 809 outputs a non-sinusoidal voltage waveform 809 upon receiving the DC voltage waveform 806 and provides the non-sinusoidal voltage waveform 809 via the RF connection 816 to the nonlinear load 801. The non-sinusoidal signal voltage waveform 809 is an example of the main non-sinusoidal voltage waveform 114 (FIG. 1) or the TES non-sinusoidal voltage waveform 116 (FIG. 1).

When the switch 808 is controlled by the processor 203 (FIG. 1) to be off during charging the nonlinear load 801, ion flux of plasma formed within the nonlinear load 801 charges one or more capacitors, such as a capacitor 812 or a capacitor 814 or a combination thereof, of the nonlinear load 801 with RF energy. Because of the charging of the one or more capacitors of the nonlinear load 801, there is an increase in voltage at the nonlinear load 801.

After the one or more capacitors of the nonlinear load 801 are charged, the switch 808 is controlled by the processor 203 to be on, such as closed. For example, the processor 203 sends an on control signal to the switch 808 to turn on the switch 808. When the switch 808 is turned on after the nonlinear load 801 is charged, the one or more capacitors of the nonlinear load 801 are discharged and the RF energy stored within the one or more capacitors is recovered for storage in the voltage source 810 of the energy recovery circuit 802. For example, during a time period in which the switch 808 is on, the RF energy is stored within the first inductor 824 in the form of electromagnetic energy to recover the RF energy. During a time period in which the RF energy is recovered, the processor 203 controls the switch 808 to turn off, such as open, after being turned on. During a time period in which the switch 808 is turned off, the electromagnetic energy stored within the first inductor 824 is transferred from the first inductor 824 via the second inductor 826 to the voltage source 810 for storage in the form of RF energy. The RF energy recovered, in this manner, is then supplied from the voltage source 810 to the combination 804 for modification of a voltage of the nonsinusoidal voltage waveform 809 output based on the DC voltage waveform 806.

Also, when the processor 203 controls the switch 808 to turn on and off to change a duty cycle of operation of the switch 808, a shape of a negative transition 803 (see FIG. 8B) of the non-sinusoidal voltage waveform 809 is controlled to achieve ion flux compensation. For example, when the switch 808 is turned on, the negative transition 803 of the non-sinusoidal voltage waveform 809 has a negative slope and it takes a shorter amount of time interval to achieve the negative transition 803. In the example, on the other end, when the switch 808 is turned off, the negative transition 803 of the non-sinusoidal voltage waveform 809 has a positive slope and it takes a greater amount of time interval to achieve the negative transition 803. As such, a time taken to achieve the negative transition 803 and a statistical slope, such as an average slope, or the negative transition 803 is increased or decreased by controlling a number of times the switch 808 is turned on and off during the negative transition 803. In the example, the negative transition 803 occurs from a time at which the non-sinusoidal voltage waveform 809 has a maximum amplitude to a time at which the non-sinusoidal voltage waveform 809 has a minimum amplitude. An example of the duty cycle of operation of the switch 808 is a time period for which the switch 808 is turned on as a percentage of a total time period for which the switch 808 is turned on and off during each cycle of the clock signal.

The duty cycle of the switch 808 is controlled to achieve pulse width modulation. As such, by controlling the switch 808, energy recovery and ion flux compensation occurs simultaneously. For example, the negative transition 803 includes a time interval of RF energy recovery and a time interval of occurrence of a ramp slope of the non-sinusoidal voltage waveform 809. The switch 808 provides the single control for the energy recovery and the ion flux compensation. The ion flux compensation occurs to achieve a predetermined sheath voltage of the lower plasma sheath to further achieve the process rate uniformity.

FIG. 8B is an embodiment of graphs 850 and 852 to illustrate operation of the system 800 of FIG. 8A. The graph 850 plots the nonsinusoidal voltage waveform 809 (FIG. 8A) output from the combination 804 (FIG. 8A) on a y-axis and the time t on an x-axis. By using the processor 203 and the energy recovery circuit 802, the negative transition 803 between an instance of the maximum amplitude of the nonsinusoidal voltage waveform 809 and an instance of the minimum amplitude of the nonsinusoidal voltage waveform 809 occurs. The negative transition 803 modifies the lower plasma sheath to be a coplanar sheath formed within the plasma chamber 102 (FIG. 1). The negative transition 803 occurs during a discharging phase and a positive slope and a substantially flat slope having the maximum amplitude occurs during a charging phase. During the charging phase, a capacitor formed by the ESC 108 and the substrate S or between the edge ring 110 (FIG. 1) and the portion 209 (FIG. 2) of the lower plasma sheath is charged by the nonsinusoidal voltage waveform 809, and during the discharging phase, the capacitor is discharged to achieve RF energy recovery.

Also, by using the processor 203 and the energy recovery circuit 802, the negative transition 803 is modified to achieve the process rate uniformity. For example, during the discharging phase, the processor 203 controls the duty cycle of the switch 808 until the amount of TES ion flux is compensated to be within the predetermined range from the compensation of the amount of main ion flux. To illustrate, the processor 203 controls the switch 808 to turn on at a first time and to turn off at a second time to achieve a first duty cycle of the switch 808. The switch 808 is turned off at the second time consecutive to the turning on of the switch 808 to achieve a first time interval between the turning on and off. In the illustration, the processor 203 determines whether the amount of TES ion flux is compensated to be within the predetermined range from the compensation of the amount of main ion flux. Further in the illustration, upon determining that the amount of TES ion flux is compensated to be outside the predetermined range from the compensation of the amount of main ion flux, the processor 203 modifies the first duty cycle. Continuing with the illustration, to achieve a second duty cycle of the switch 808, the processor 203 controls the switch 808 to turn on at a third time and to turn off at a fourth time. The switch 808 is turned off at the fourth time consecutive to the turning on of the switch 808 to achieve a second time interval between the turning on and off. The second time interval is different from, such as greater than or lower than, the first time interval. In this manner, the processor 203 continues to modify the duty cycle of operation of the switch 808 until it is determined that the amount of TES ion flux is compensated to be within the predetermined range from the compensation of the amount of main ion flux. When the amount of TES ion flux is compensated to be within the predetermined range from the compensation of the amount of main ion flux, the process rate uniformity between the main region 208 and the edge region 212 (FIG. 2) is achieved. The graph 852 plots a logic state, such as an on state or an off state, of the switch 808 (FIG. 8A) on a y-axis and the time t on an x-axis. The x-axis of the graph 850 is the same as the x-axis of the graph 852.

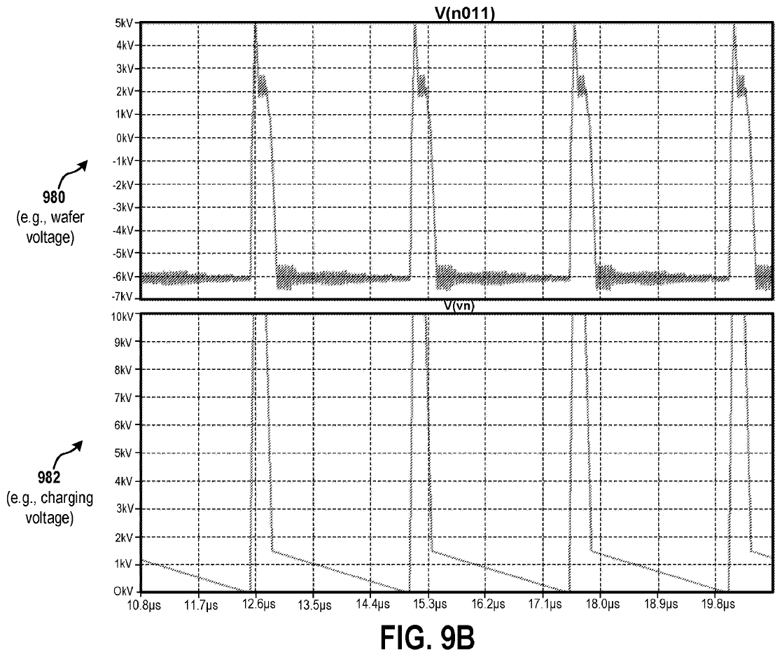

FIG. 9A is an embodiment of a system 900 to illustrate use of an energy recovery circuit 902 to recover energy from the plasma chamber 102 (FIG. 1). An example of the energy recovery circuit 902 is the energy recovery circuit 802 (FIG. 8A). The system 900 includes a combination 904 of HV supplies. The combination 904 is an example of the main combination 512 or the TES combination 518 (FIG. 5). The system 900 further includes the energy recovery circuit 902 that is coupled in parallel to the combination 904 and to a plasma load 906. The energy recovery circuit 902 is an example of the main energy recovery circuit 520 on the TES energy recovery circuit 522 (FIG. 5). An example of the plasma load 906 is the plasma chamber 102 (FIG. 1).

The combination 904 is coupled to the plasma load 906 via an RF connection 903. The RF connection 903 is an example of the RF connection 314 or 316 (FIG. 3). The energy recovery circuit 902 is coupled to a point 905 on the RF connection 903. An example of the point 905 is the point 818 (FIG. 8A).

The combination 904 outputs a DC voltage waveform 905, which is provided to a diode and a resonant inductor of the RF connection 903 to output a non-sinusoidal voltage waveform 907. The non-sinusoidal voltage waveform 907 is an example of the main non-sinusoidal voltage waveform 114 or the TES non-sinusoidal voltage waveform 116 (FIG. 1). An example of the DC voltage waveform output from the combination 904 is the modified main DC voltage waveform 517 (FIG. 5). Another example of the DC voltage waveform 905 output from the combination 904 is the modified TES DC voltage waveform 519 (FIG. 5). The processor 203 (FIG. 2) controls the combination 904 to shape the non-sinusoidal voltage waveform 907. For example, the processor 203 controls the combination 904 to control the positive slope during the charging phase or the maximum amplitude during the charging phase or a combination thereof of the non-sinusoidal voltage waveform 907.

The energy recovery circuit 902 includes a switch 908, a DC source 910, the inductor 824, the inductor 826, and a diode 914. An example of the DC source 910 is the main capacitor 510 or the TES capacitor 516 (FIG. 5). To illustrate, the DC source 910 represents a voltage across the main DC source 508 and the voltage is the same as that across the main capacitor 510. As another illustration, the DC source 910 represents a voltage across the TES DC source 514 and the voltage is the same as that across the TES capacitor 516. The inductor 826 is coupled in series with the diode 914, which is coupled in series with the DC source 910.

When the switch 908 is controlled to close by the processor 203, voltage at the plasma load 906 discharges to charge the inductor 824. For example, RF energy of the plasma load 906 is stored in the form of electromagnetic energy by the inductor 824. On the other hand, when the switch 908 is open, the electromagnetic energy stored in the inductor 824 is transferred to the DC source 910 via the diode 914 for storage of the RF energy.

The energy recovery circuit 902 acts as a switch 901 to provide a predetermined amount of voltage to the plasma load 906. For example, when the switch 901 acts as an open, the combination 904 generates the DC voltage waveform 905, which is then used to output the non-sinusoidal voltage waveform 907 having a maximum amplitude of 10 kilovolts (kV) and the same maximum amplitude is achieved at an input I1 of the plasma load 906. When the switch 901 acts as closed, the energy recovery circuit 902 stores RF energy from the plasma load 906 to reduce the maximum amplitude from 10 kV to 5 kV. As such, the voltage at the input I1 reduces to 5 kV without modifying the maximum amplitude output from the combination 904. The switch 901 acts as being closed and the energy recovery circuit 902 stores RF energy recovered from the plasma load 906 to reduce the voltage at the input I1 from 5 kV to 3 kV. An example of the switch 901 is the switch 908. When the voltage at the input I1 is to be increased from 3 kV back to 10 kV, the switch 901 is controlled by the processor 203 to be open and the non-sinusoidal voltage waveform 907 increases the voltage at the input I1 back to 10 kV.

FIG. 9B is an embodiment of a graph 980 and another graph 982 to illustrate operation of the system 900 (FIG. 9A). The graph 980 plots sheath voltage of plasma formed within the plasma chamber 102 on a y-axis and the time t on an x-axis. For example, the graph 980 plots the sheath voltage in the main region 208 or the edge region 212 (FIG. 2). The graph 982 plots a voltage of the non-sinusoidal voltage waveform 907 (FIG. 9A) on a y-axis and the time t on an x-axis. The x-axis of the graph 982 is the same as the x-axis of the graph 980.

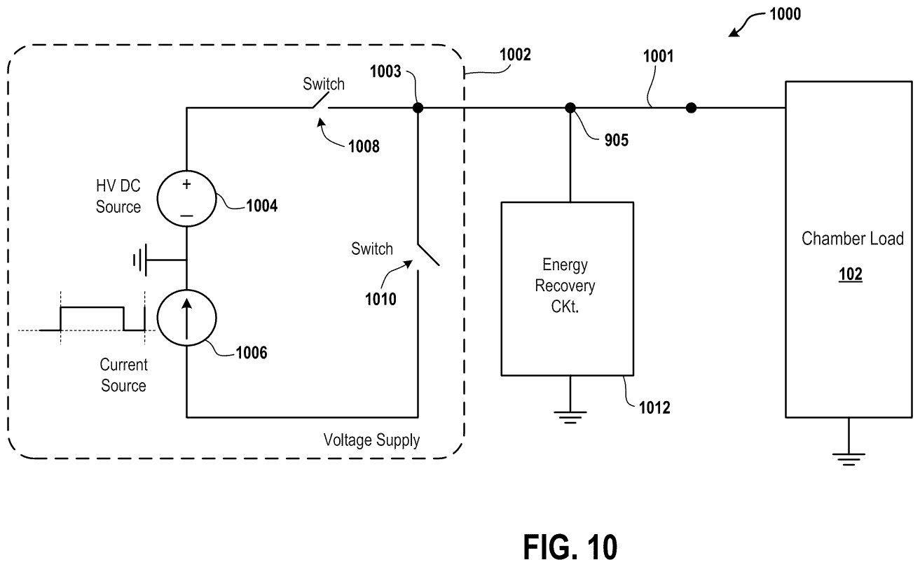

FIG. 10 is a diagram of an embodiment of a system 1000 to illustrate use of a voltage supply 1002. The voltage supply 1002 includes an HVDC source 1004, which includes a combination of HV supplies. The combination of HV supplies of the HVDC source 1004 is also an example of the main combination 512 or the TES combination 518 (FIG. 5). An example of the HVDC source 1004 is the main power supply 504 or the TES power supply 506 (FIG. 5). The voltage supply 1002 includes a current source 1006, a switch 1008, and another switch 1010. The system 1000 further includes an energy recovery circuit 1012 and the plasma chamber 102. An example of the energy recovery circuit 1012 is the energy recovery circuit 802 (FIG. 8A) or 902 (FIG. 9A).

The combination of HV supplies of the HVDC source 1004 is coupled to the switch 1008 in series. The switch 1008 is coupled via an RF connection 1001 to the plasma chamber 102. The RF connection 1001 is an example of the RF connection 903 (FIG. 9A). The switch 1010 is coupled at a point 1003 on the RF connection 1001 and is coupled to the current source 1006. The current source 1006 is coupled to a ground potential and the combination of HV supplies of the HVDC source 1004 is also coupled to the ground potential. The processor 203 is coupled to the switches 1008 and 1010.

During the charging phase, the processor 203 controls the switch 1008 to close and controls the switch 1010 to open. During the discharging phase, the processor 203 controls the switch 1008 to open and the switch 1010 is open. After RF energy is recovered from the plasma chamber 102 during the discharging phase, the processor 203 (FIG. 2) controls the switch 1010 to close to achieve the ion flux compensation. When the switch 1010 is closed, current flows from the plasma chamber towards the current source 1006. To achieve the ion flux compensation, the processor 203 controls the switch 1008 to be open.

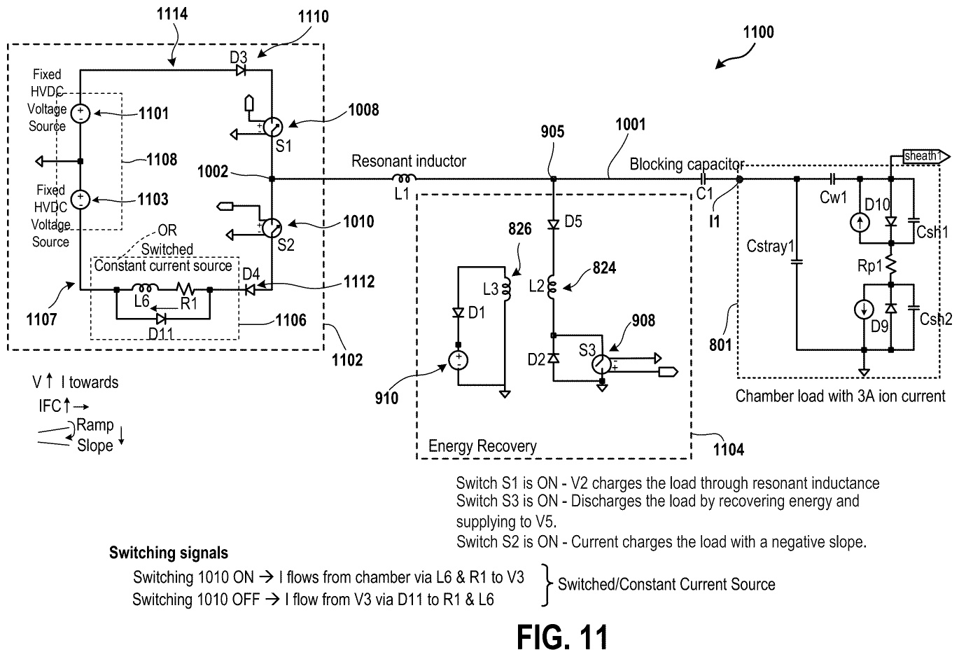

FIG. 11 is a diagram of an embodiment of a system 1100 to illustrate details of charging and ion flux compensation within the system 1000 (FIG. 10). The system 1100 includes a voltage supply system 1102, an energy recovery circuit 1104, and the nonlinear load 801. The voltage supply system 1102 is an example of the voltage supply 1002 of FIG. 10. The energy recovery circuit 1104 is an example of the energy recovery circuit 1012 (FIG. 10). The voltage supply system 1102 includes a constant current source 1106 and a voltage source system 1108. The constant current source 1106 includes a resistor, or an inductor, and a diode. The voltage source system 1108 includes a voltage source 1101 and another voltage source 1103. An example of the voltage source 1101 is a part of the main combination 512 or TES combination 518 (FIG. 5). As an example, the voltage source 1103 is a part of the main combination 512 or TES combination 518. The voltage supply system 1102 further includes multiple diodes 1110 and 1112, and the switches 1008 and 1010. The energy recovery circuit 1104 includes the DC source 910.

The voltage source 1103, the constant current source 1106, and the switch 1010 form an ion flux compensation circuit, such as a main ion flux compensation circuit or a TES ion flux compensation circuit. For example, the main ion flux compensation circuit is coupled to the main electrode via the RF connection 314 (FIG. 3) and the TES ion flux compensation circuit is coupled to the edge ring 110 via the RF connection 316 (FIG. 3).

The resistor of the constant current source 1106 is coupled in series with the inductor of the constant current source 1106 to form a series circuit, and the series circuit is coupled in parallel with the diode of the constant current source 1106 to form a parallel circuit. The constant current source 1106 is coupled in series to the diode 1112, which is coupled to the switch 1010 in series. The point 1003 between the switches 1008 and 1110 is connected to the nonlinear load 801 via an inductor 1105 and a capacitor 1107. Also, there is a ground connection between the voltage sources 1101 and 1103. The voltage source 1101 is coupled via the diode 1110 to the switch 1008 and the voltage source 1103 is coupled via the constant current source 1106 to the diode 1112. The processor 203 (FIG. 2) is coupled to the voltage sources 1101 and 1103.

The voltage source 1101 generates a DC voltage waveform 1114, such as the modified main DC voltage waveform 517 or the modified TES DC voltage waveform 519 (FIG. 5). The DC voltage waveform 1114 is provided from the voltage supply 1101 to a circuit including a combination of the inductor 1105 and the capacitor 1107, and the circuit converts the DC voltage waveform 1114 into a non-sinusoidal voltage waveform 1109, such as the main non-sinusoidal voltage waveform 114 or the TES non-sinusoidal voltage waveform 116 (FIG. 1). The processor 203 controls the switch 1008 to close and the switch 1010 to open. Once the switch 1008 closes, the DC voltage waveform 1114 is sent via the diode 1110 and the switch 1008 to the inductor 1105 to output the non-sinusoidal voltage waveform 1109. The non-sinusoidal voltage waveform 1109 is sent from the voltage supply system 1102 to the nonlinear load 801 to charge the nonlinear load 801 with RF energy during the charging phase. After the nonlinear load 801 is charged, the processor 203 controls the switch 908 to close. When the switch 908 is closed, the inductor 824 charges from the RF energy recovered from the nonlinear load 801 during the discharging phase. Also, the processor 203 controls the switch 908 to open during the discharging phase. When the switch 908 is open, the RF energy stored within the inductor 824 charges the DC source 910 of the energy recovery circuit 1104 with RF energy. The RF energy stored within the DC source 910 is provided to the voltage source system 1108 to modify an amplitude of the non-sinusoidal voltage waveform 1109.

After the discharging phase, during an ion compensation phase, processor 203 controls the switch 1010 to close and controls the switch 1008 to open. When the switch 1010 closes, a current is supplied from the voltage source system 1108 to the nonlinear load 801 in a negative manner, such as in a negative direction. For example, when the switch 1010 is closed, a current signal 1107 flows from the nonlinear load 801 via the RF connection 1001, the point 905, the switch 1110, the diode 1112, and the resistor and the inductor of the constant current source 1106 towards the voltage source 1103. Moreover, the processor 203 controls the switch 1010 to open after being closed. When the switch 1010 is open, the current signal 1107 that is output from the voltage source 1103 flows via the diode of the constant current source 1112 and the resistor of the constant current source 1112 to the inductor of the constant current shows 1112. It should be noted that when the current signal 1107 flows from the nonlinear load 801 towards the voltage source 1103, the current signal 1107 is flowing in a positive direction and is represented by a positive value. On the other hand, when the current signal 1107 flows from the voltage source 1103 towards the nonlinear load 801, the current signal 1107 is flowing in a negative direction and is represented by a negative value. Because there is current flow within the constant current source 1106 when the switch 1010 is open or closed, the constant current source 1106 is termed as a constant current source.

The processor 203 controls a voltage of the voltage source 1103 to achieve the process rate uniformity. For example, upon receiving an amount of the main ion flux and an amount of the TES ion flux, the processor 203 controls the voltage source 1103 to modify, such as increase or decrease, a voltage output from the voltage source 1103 until the amount of TES ion flux is compensated to be within the predetermined range from the compensation of the amount of main ion flux. The voltage, such as a negative voltage, output from the voltage source 1103 is modified to change, such as increase or decrease, an amount of current, such as a magnitude, of the current signal 1107. The magnitude of the current signal 1107 is modified to change the ramp slope of the non-sinusoidal voltage waveform 1109 during the ion compensation phase. For example, when the voltage output from the voltage source 1103 increases, the magnitude of the current signal 1107 increases and the ramp slope of the non-sinusoidal voltage waveform 1109 increases in magnitude, e.g., becomes more negative from zero. On the other hand, when the voltage output from the voltage source 1103 decreases, the magnitude of the current signal 1107 decreases and the ramp slope of the non-sinusoidal voltage waveform 1109 decreases in magnitude, e.g., approaches zero from a negative value.

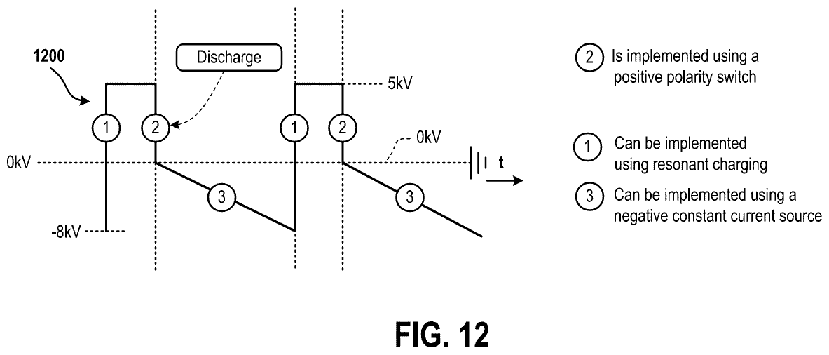

FIG. 12 is an embodiment of a graph 1200 to illustrate the charging phase, the discharging phase, and the ion compensation phase. As an example, the graph 1200 plots a voltage at the input I1 of the nonlinear load 801 (FIG. 11) on a y-axis and the time t on an x-axis. As another example, the graph 200 plots a voltage of the main non-sinusoidal voltage waveform 114 or the TES non-sinusoidal voltage waveform 116 (FIG. 1) on the y-axis and the time t on the x-axis. Referring back to FIG. 11, during the charging phase, when the switch 1008 is closed and the switch 1010 (FIG. 11) is open, a transition, illustrated using a number “1”, of the voltage occurs from a negative voltage, such as −8 kV, to a positive voltage, such as 5 kV, to charge the plasma chamber 102 with RF energy of the non-sinusoidal voltage waveform 1109 (FIG. 11). For example, RF energy of the DC voltage waveform 1114 is transferred from the voltage source 1101 via the diode 1110, the switch 1108, and the point 1003 to the inductor 1105 of the RF connection 1001 to output the nonsinusoidal voltage waveform 1114, and RF energy of the nonsinusoidal voltage waveform 1114 is transferred via the RF connection 1001 to the nonlinear load 801. After the plasma of the plasma chamber 102 illustrated by the nonlinear load 801 is charged, during the discharging phase, the switch 908 (FIG. 11) is closed, and discharge of RF energy of the plasma occurs to charge the inductor 824. The charging of the inductor 824 reduces the positive voltage, such as 5 kV, to a zero voltage. A transition from the positive voltage to the zero voltage is illustrated using a number “2”.

During the ion compensation phase, a transition, illustrated using a number “3”, from the zero voltage to the negative voltage occurs using the constant current source 1106 (FIG. 11). For example, when the switch 1008 is open and the switch 1010 is closed, the transition from the zero voltage to the negative voltage occurs. To illustrate, power is being supplied from the voltage source 1103 to the nonlinear load 801 but in the negative direction. For example, the current signal 1107 is a current that flows from the nonlinear load 801 to the voltage source 1103 via the resistor and inductor of the constant current source 1106. The negative direction is from the nonlinear load 801 to the voltage source 1103 via the switch 1010 and the resistor and inductor of the constant current source 1106.

In this manner, the charging phase, the discharging phase, and the ion compensation phase repeat periodically, e.g., during each cycle of the clock signal. For example, after the ion compensation phase, the switch 1008 is again controlled by the processor 203 to be closed and the switch 1010 is again controlled by the processor 203 to be open, a transition, illustrated using the number “1”, of the voltage occurs from the negative voltage to the positive voltage, such as 5 kV. For example, RF energy of the nonsinusoidal voltage waveform 1114 is transferred from the voltage source 1101 to the nonlinear load 801.

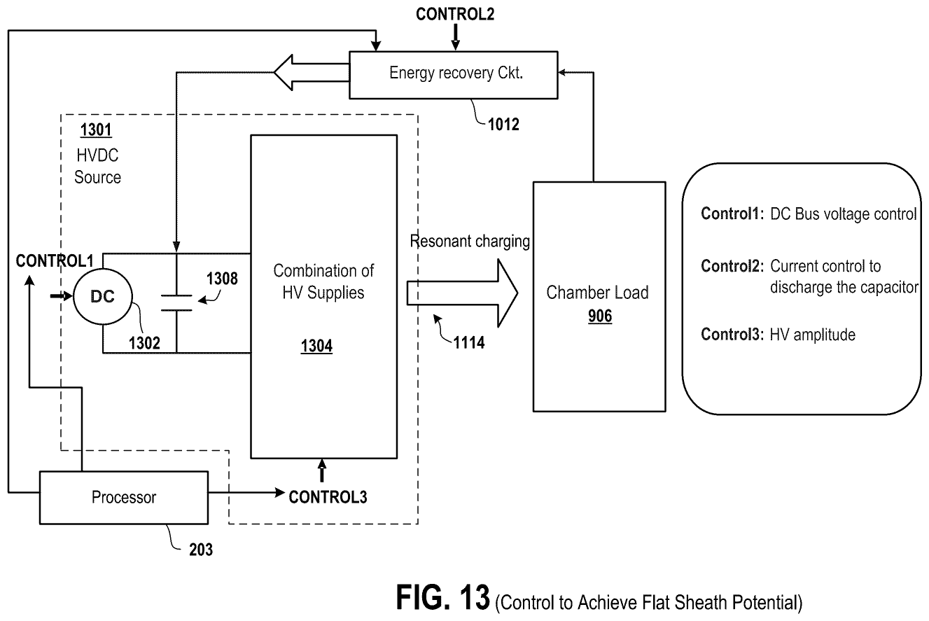

FIG. 13 is an embodiment of a system 1300 to illustrate a control of a DC supply 1302, a combination 1304 of HV supplies, the energy recovery circuit 1012, a capacitor 1308, and the plasma load 906 to achieve the process rate uniformity. The DC source 1302, capacitor 1308, and the combination 1304 are components of an HVDC source 1301. The HVDC source 1301 is an example of the main power supply 306 (FIG. 3) or the TES power supply 308 (FIG. 3).

The DC supply 1302 is an example of the main DC source 508 or the TES DC source 514 (FIG. 5). For example, a combination of the DC supply 1302, the capacitor 1308, and the combination 1304 is an example of the DC source 1004 (FIG. 10). Also, the combination 1304 is an example of the main combination 512 or the TES combination 518 (FIG. 5). Moreover, the capacitor 1308 is an example of the capacitor 510 or 516 (FIG. 5). The energy recovery circuit 1012 is an example of the main energy recovery circuit 520 or the TES energy recovery circuit 522 (FIG. 5). To illustrate, the energy recovery circuit 802 (FIG. 8A) or the energy recovery circuit 902 (FIG. 9A) is an example of the energy recovery circuit 1012.

The system 1300 further includes processor 203. The processor 203 controls one or more of the DC supply 1302, the combination 1304, and the energy recovery circuit 1012 to achieve the process rate uniformity. For example, voltage sensors sense voltages, such as a main voltage associated with the main electrode and a TES voltage associated with the edge ring 110. To illustrate, a voltage sensor senses a voltage at an input of the main electrode and another voltage at an input of the edge ring 110, to achieve the process rate uniformity. Based on the voltages, the processor 203 controls the DC source 1302 or the combination 1304 or both to control, such as increase or decrease, an amplitude, such as the maximum amplitude, of the non-sinusoidal voltage waveform 1109 output based on the DC voltage waveform 1114. The DC voltage waveform 1114 is generated by the combination 1304. As another example, ion flux sensors sense the amount of main ion flux associated with the main electrode and the amount of TES ion flux associated with the edge ring 110. Based on the amounts of main and TES ion fluxes, the processor 203 controls the DC source 1302 or one or more HV supplies of the combination 1304 to modify, such as increase or decrease, an amplitude of the non-sinusoidal voltage waveform 1109. As yet another example, based on amounts of main ion flux and TES ion flux, the processor 203 controls the energy recovery circuit 1012 to modify, such as increase or decrease, a negative slope of the voltage of the non-sinusoidal voltage waveform 1109 during the discharging phase. The negative slope is an example of a negative transition of the non-sinusoidal voltage waveform 1109 from a maximum amplitude of the non-sinusoidal voltage waveform 1109. Similarly, the processor 203 controls one or more of the HVDC source 1301, the energy recovery circuit 1012, and the voltage source 1103 (FIG. 11) until the amount of TES ion flux is compensated to be within the predetermined range from the compensation of the amount of main ion flux. The non-sinusoidal voltage waveform 1109 is an example of the main non-sinusoidal voltage waveform 114 (FIG. 1) or of the TES non-sinusoidal voltage waveform 116 (FIG. 1).

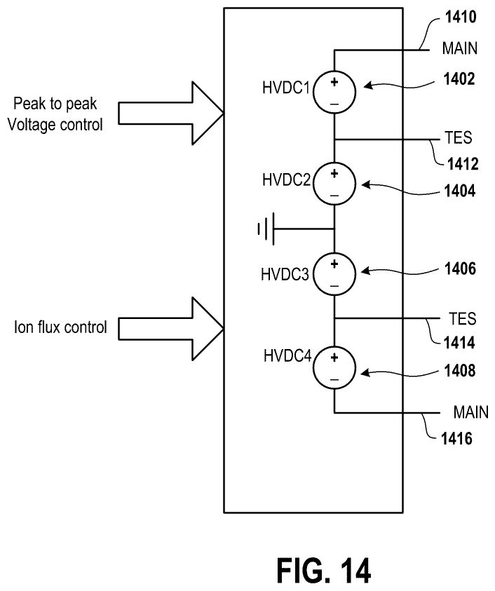

FIG. 14 is a diagram of an embodiment of an integrated combination 1400 of HV supplies. The combination 1400 includes a voltage source 1402, another voltage source 1404, another voltage source 1406, and another voltage source 1408. An output 1410 and another output 1416 of the combination 1400 is coupled to the main electrode. An output 1412 and another output 1414 of the combination 1400 is coupled to the edge ring 110 (FIG. 1).

The voltage sources 1402 and 1404 are controlled by the processor 203 (FIG. 13) to achieve peak-to-peak voltage control of non-sinusoidal voltage waveforms that are generated based on DC voltage waveforms supplied from the outputs 1410 and 1412. The non-sinusoidal voltage waveforms are supplied to the main electrode and the edge ring 110. Also, the voltage sources 1406 and 1408 are controlled by the processor 203 to achieve the ion flux compensation using the non-sinusoidal voltage waveforms.

Embodiments described herein may be practiced with various computer system configurations including hand-held hardware units, microprocessor systems, microprocessor-based or programmable consumer electronics, minicomputers, mainframe computers and the like. The embodiments can also be practiced in distributed computing environments where tasks are performed by remote processing hardware units that are linked through a network.

In some embodiments, a controller, described herein, is a part of a system, which may be part of the above-described examples. Such systems include semiconductor processing equipment, including a processing tool or tools, chamber or chambers, a platform or platforms for processing, and/or specific processing components (a wafer pedestal, a gas flow system, etc.). These systems are integrated with electronics for controlling their operation before, during, and after processing of a semiconductor wafer or substrate. The electronics is referred to as the “controller,” which may control various components or subparts of the system or systems. The controller, depending on the processing requirements and/or the type of system, is programmed to control any of the processes disclosed herein, including the delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks coupled to or interfaced with a system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer, which allows for remote access of the wafer processing. The computer enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to a system over a network, which includes a local network or the Internet. The remote computer includes a user interface that enables entry or programming of parameters and/or settings, which are then communicated to the system from the remote computer. In some examples, the controller receives instructions in the form of data, which specify the parameters, factors, and/or variables for each of the processing steps to be performed during one or more operations. It should be understood that the parameters, factors, and/or variables are specific to the type of process to be performed and the type of tool that the controller is configured to interface with or control. Thus as described above, the controller is distributed, such as by including one or more discrete controllers that are networked together and working towards a common purpose, such as the processes and controls described herein. An example of a distributed controller for such purposes includes one or more integrated circuits on a chamber in communication with one or more integrated circuits located remotely (such as at the platform level or as part of a remote computer) that combine to control a process on the chamber.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a capacitively coupled plasma (CCP) chamber, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

As noted above, depending on the process step or steps to be performed by the tool, the host computer communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These operations are those physically manipulating physical quantities. Any of the operations described herein that form part of the embodiments are useful machine operations.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations may be processed by a computer selectively activated or configured by one or more computer programs stored in a computer memory, cache, or obtained over the computer network. When data is obtained over the computer network, the data may be processed by other computers on the computer network, e.g., a cloud of computing resources.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), read-only memory (ROM), random access memory (RAM), compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment described above are combined with one or more features of any other embodiment without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A system comprising:
a first power supply including:
a first direct current (DC) power source configured to generate a first DC voltage waveform;
a first capacitor coupled in parallel to the first DC power source; and
a first plurality of voltage supplies coupled to the first capacitor, wherein the first plurality of voltage supplies is configured to receive the first DC voltage waveform to facilitate output of a first non-sinusoidal voltage waveform to a main electrode of a plasma chamber;
a second power supply including:
a second DC power source configured to generate a second DC voltage waveform;
a second capacitor coupled in parallel to the second DC power source; and
a second plurality of voltage supplies coupled to the second capacitor, wherein the second plurality of voltage supplies is configured to receive the second DC voltage waveform to facilitate output of a second non-sinusoidal voltage waveform to an edge electrode of the plasma chamber; and
a controller coupled to the first and second pluralities of voltage supplies to control a plurality of amplitudes of the first and second non-sinusoidal voltage waveforms to achieve process rate uniformity between a main region and an edge region in the plasma chamber.

2. The system of claim 1, further comprising:
an energy recovery circuit coupled to the plasma chamber, wherein the energy recovery circuit is configured to receive radio frequency (RF) energy from the plasma chamber and store the RF energy.

3. The system of claim 2, wherein the energy recovery circuit includes an inductor configured to store the RF energy.

4. The system of claim 3, wherein the energy recovery circuit includes a switch, wherein the controller is coupled to the switch to control a time period for which the RF energy is recovered for storage in the inductor, wherein the time period for which the RF energy is recovered for storage controls a negative transition of the first or second non-sinusoidal voltage waveform to facilitate achievement of the process rate uniformity.

5. The system of claim 1, wherein the controller is coupled to the first and second DC power sources to control DC voltages of the first and second DC power sources to modify the plurality of amplitudes of the first and second non-sinusoidal voltage waveforms.

6. The system of claim 1, wherein the controller is configured to control phases of the first and second non-sinusoidal voltage waveforms.

7. The system of claim 1, further comprising a clock source coupled to the first and second power supplies to synchronize the first and second non-sinusoidal voltage waveforms.

8. The system of claim 1, wherein the plasma chamber is a nonlinear load, wherein the controller is configured to control a plurality of slopes of a plurality of ramps of the first and second non-sinusoidal voltage waveforms to achieve the process rate uniformity.

9. A method comprising:
generating, by a first direct current (DC) power source, a first DC voltage waveform;
receiving the first DC voltage waveform to facilitate output of a first non-sinusoidal voltage waveform to a main electrode of a plasma chamber;
generating, by a second DC power source, a second DC voltage waveform;
receiving the second DC voltage waveform to facilitate output of a second non-sinusoidal voltage waveform to an edge electrode of the plasma chamber; and
controlling a plurality of amplitudes of the first and second non-sinusoidal voltage waveforms to achieve process rate uniformity between a main region and an edge region in the plasma chamber.

10. The method of claim 9, further comprising:
receiving radio frequency (RF) energy from the plasma chamber; and
storing the RF energy within an energy recovery circuit.

11. The method of claim 10, wherein the RF energy is stored within an inductor.

12. The method of claim 11, wherein the energy recovery circuit includes a switch, the method further comprising controlling a time period for which the RF energy is recovered for storage in the inductor, wherein the time period for which the RF energy is recovered for storage controls a negative transition of the first or second non-sinusoidal voltage waveform to facilitate achievement of the process rate uniformity.

13. The method of claim 9, further comprising controlling DC voltages of the first and second DC power sources to modify the plurality of amplitudes of the first and second non-sinusoidal voltage waveforms.

14. The method of claim 9, further comprising controlling phases of the first and second non-sinusoidal voltage waveforms.

15. The method of claim 9, further comprising synchronizing operations of the first and second DC power sources.

16. The method of claim 9, wherein the plasma chamber is a nonlinear load.

17. A non-transitory computer readable medium containing program instructions for controlling non-sinusoidal radio frequency (RF) signals supplied to a main electrode and an edge electrode of a plasma chamber, wherein execution of the program instructions by one or more processors of a computer system causes the one or more processors to carry out operations of:
generating, by a first direct current (DC) power source, a first DC voltage waveform;
receiving the first DC voltage waveform to facilitate output of a first non-sinusoidal voltage waveform to the main electrode of the plasma chamber;
generating, by a second DC power source, a second DC voltage waveform;
receiving the second DC voltage waveform to facilitate output of a second non-sinusoidal voltage waveform to the edge electrode of the plasma chamber; and
controlling a plurality of amplitudes of the first and second non-sinusoidal voltage waveforms to achieve process rate uniformity between a main region and an edge region in the plasma chamber.

18. The non-transitory computer readable medium of claim 17, wherein the operations further comprise:
receiving RF energy from the plasma chamber; and
storing the RF energy within an energy recovery circuit.

19. The non-transitory computer readable medium of claim 18, wherein the RF energy is stored within an inductor.

20. The non-transitory computer readable medium of claim 19, wherein the energy recovery circuit includes a switch, wherein the operations comprise controlling a time period for which the RF energy is recovered for storage in the inductor, wherein the time period for which the RF energy is recovered for storage controls a negative transition of the first or second non-sinusoidal voltage waveform to facilitate achievement of the process rate uniformity.

21. A system for use with a plasma chamber, the plasma chamber having a substrate support and an edge ring surrounding the substrate support, comprising:
a voltage waveform source;
a first output of the voltage waveform source connected to the substrate support;
a second output of the voltage waveform source connected to the edge ring; and
a controller configured to control the voltage waveform source to output a first non-sinusoidal bias (NSB) waveform for the substrate support and a second NSB waveform for the edge ring via the second output,
wherein the first and second NSB waveforms provide pulsed biasing voltages to plasma generated in the plasma chamber.

22. The system of claim 21, wherein the voltage waveform source includes a direct current (DC) supply, a capacitor coupled in parallel to the DC supply, and a combination of voltage supplies coupled in parallel to the DC supply.

23. The system of claim 22, further comprising an energy recovery circuit coupled to the capacitor, wherein the energy recovery circuit is configured to recover and store radio frequency (RF) energy from the plasma chamber.

24. The system of claim 23, wherein the energy recovery circuit is configured to provide the RF energy to the combination of voltage supplies, wherein the combination of voltage supplies is configured to modify the first NSB waveform or the second NSB waveform based on the RF energy.

25. The system of claim 21, further comprising an ion flux compensation circuit having a voltage source, wherein the controller is configured to control a voltage output from the voltage source of the ion flux compensation circuit to control a slope of a ramp of the first or second NSB waveform.
